(19) United States
(12) Patent Application Publication
(10) Pub. No.: US 2023/0178347 A1
(43) Pub. Date: Jun. 8, 2023

(54) PREPARATION METHOD OF HYDROGENATED COMPOSITE FILM AND OPTICAL FILTER

(71) Applicant: ZHEJIANG CRYSTAL-OPTECH CO., LTD., Zhejiang (CN)

(72) Inventors: Yanzhi WANG, Zhejiang (CN); Yonghui WU, Zhejiang (CN); Ren LU, Zhejiang (CN); Ruizhi ZHANG, Zhejiang (CN); Jun YAO, Zhejiang (CN); Jinlong CHEN, Zhejiang (CN); Lijian JIN, Zhejiang (CN); Fenglei LIU, Zhejiang (CN); Jian TANG, Zhejiang (CN)

(73) Assignee: ZHEJIANG CRYSTAL-OPTECH CO., LTD., Zhejiang (CN)

(21) Appl. No.: 17/997,975

(22) PCT Filed: Jul. 8, 2021
(86) PCT No.: PCT/CN2021/105226

§ 371 Date: Nov. 5, 2022

(30) Foreign Application Priority Data
Apr. 7, 2021 (CN) 202110375212.8

(51) Int. Cl. H01J 37/34; H01J 37/32; G02B 5/20; G02B 5/28; C03C 17/36

(52) U.S. Cl. CPC H01J 37/3414; H01J 37/32449; G02B 5/207; G02B 5/281; C03C 17/3657; C03C 17/3649; H01J 2237/332; C03C 2217/259; C03C 2217/258; C03C 2217/268; C03C 2217/28; C03C 2218/155

(57) ABSTRACT

The present application provides a preparation method of a hydrogenated composite film and an optical filter, and relates to the field of optical film filter technologies. The preparation method includes: introducing inert gas and hydrogen into a reaction chamber, and bombarding at least two materials in the reaction chamber and the introduced hydrogen using plasma formed by the inert gas, such that the at least two materials are sputtered onto a substrate and react with hydrogen ions generated by the hydrogen to form a hydrogenated composite film layer. The hydrogenated composite film layer includes at least two materials which are co-sputtered onto the same substrate using the sputtering technology to obtain a required material performance, so as to obtain the hydrogenated composite film layer with a refractive index greater than 3.5 and an extinction coefficient less than 0.005 under a wavelength of 700 nm to 1800 nm.

### CROSS-REFERENCE TO RELATED APPLICATIONS

The present application claims priority to Chinese Patent Application No. 2021103752128, entitled “Preparation Method of Hydrogenated Composite Film and Optical Filter”, filed with China National Intellectual Property Administration on Apr. 7, 2021, the entire content of which is incorporated herein by reference.

### TECHNICAL FIELD

The present application relates to the field of optical film filter technologies, and particularly to a preparation method of a hydrogenated composite film and an optical filter.

### BACKGROUND ART

In a case where light is incident at a large angle, a narrow-band-pass optical filter in a near-infrared imaging system, such as a 3D near-infrared imaging system, or the like, is required to have minimized offset of a center wavelength with an angle, such that signal loss is small and a signal-to-noise ratio is high in a wide view field angle range, so as to produce a large-angle low-offset effect.

The narrow-band-pass optical filter meeting the above-mentioned functional requirement is necessary to be manufactured by mutually superimposing a coating material with an ultrahigh refractive index and a coating material with a medium and low refractive index for coating.

Currently, a hydrogenated silicon material is generally adopted as the high refractive index material for manufacturing the optical filter with the large-angle low-offset effect, and fabrication of the hydrogenated silicon material is mainly protected by foreign patents, which means that a thus manufactured product is always subject to the foreign patents, also resulting in a high product cost. In addition, the hydrogenated silicon material has an insufficiently good offset effect and an insufficiently large view field angle, such that the optical filter made of such a material has a limited large-angle low-offset effect.

### SUMMARY

An object of embodiments of the present application is to provide a preparation method of a hydrogenated composite film and an optical filter, the method being able to improve an overall performance of the film and reduce a product cost.

In addition, there is provided a preparation method of a hydrogenated composite film, including: introducing inert gas and hydrogen into a reaction chamber, and bombarding at least two materials in the reaction chamber and the introduced hydrogen using plasma formed by the inert gas, such that the at least two materials are sputtered onto a substrate and react with hydrogen ions generated by the hydrogen to form a hydrogenated composite film layer.

Optionally, the at least two materials include a main material and at least one auxiliary material, and the main material includes silicon or germanium; the auxiliary material includes at least one of a semiconductor material, a fourth main group element, and a transition element, and the main material and the auxiliary material are different materials.

Optionally, the main material is silicon, and the auxiliary material is germanium; or the main material is silicon, and the auxiliary material is niobium; or the main material is silicon, and the auxiliary material is titanium.

Optionally, mass of the auxiliary material accounts for less than 20% of total raw material mass.

Optionally, the introducing inert gas and hydrogen into a reaction chamber, and bombarding at least two materials in the reaction chamber and the introduced hydrogen using plasma formed by the inert gas, such that the at least two materials are sputtered onto a substrate and react with hydrogen ions generated by the hydrogen to form a hydrogenated composite film layer includes: controlling sputtering parameters and flow rates of the introduced inert gas and hydrogen to form the hydrogenated composite film layer with a refractive index greater than 3.5 and an extinction coefficient less than 0.005 under a wavelength of 700 nm to 1800 nm.

Optionally, the sputtering parameters include sputtering power, a sputtering voltage, a sputtering current, a sputtering time and a sputtering temperature.

Optionally, one or more target materials exist in the reaction chamber, the target materials are prepared from the materials, one target material may be prepared from only one material, or one target material may be prepared from two or more materials.

Optionally, the inert gas introduced into the reaction chamber has a flow rate less than 800 standard milliliters per minute.

Optionally, the hydrogen introduced into the reaction chamber has a flow rate less than 400 standard milliliters per minute.

Optionally, the inert gas is argon.

The present application further provides an optical filter, including: a substrate, a hydrogenated composite film layer laminated on the substrate and fabricated using the above-mentioned preparation method of a hydrogenated composite film, and a first film layer; the first film layer having a lower refractive index than the hydrogenated composite film layer.

Optionally, the substrate is provided with a plurality of hydrogenated composite film layers and a plurality of first film layers, and the plurality of hydrogenated composite film layers and the plurality of first film layers are arranged alternately.

Optionally, the first film layer is a medium-low refractive index material layer.

Optionally, the first film layer is made of silicon oxide or silicon hydroxide.

### BRIEF DESCRIPTION OF DRAWINGS

To describe the technical solutions in the embodiments of the present application more clearly, the following briefly describes the accompanying drawings required in the embodiments of the present application. It should be understood that the following accompanying drawings show merely part of content of the present application and therefore should not be considered as limiting the scope, and a person of ordinary skill in the art may still derive other related drawings from these accompanying drawings without creative efforts.

FIG. 1 is an arrangement diagram of a preparation device of a hydrogenated composite film in an embodiment;

FIG. 2 is a graph of a relationship between a wavelength and a refractive index under different hydrogen conditions in the embodiment;

FIG. 3 is a graph of a relationship between the wavelength and an extinction coefficient under different hydrogen conditions in the embodiment;

FIG. 4 is a performance parameter graph of a single layer of hydrogenated germanium silicon in the embodiment; and

FIG. 5 is a graph of an optical filter designed with hydrogenated germanium silicon as a high refractive index material in the embodiment.

### REFERENCE NUMERALS

101-substrate; A, B-target material; Q-inert gas; H₂ -hydrogen.

### DETAILED DESCRIPTION

The technical solutions in the embodiments of the present application are clearly and completely described with reference to the accompanying drawings in the embodiments of the present application.

In descriptions of the present application, it should be noted that, directions or positional relationships indicated by terms “inner”, “outer”, etc. are based on orientations or positional relationships shown in the accompanying drawings, or orientations or positional relationships of conventional placement of the product according to the present application in use, and they are used only for describing the present application and for description simplicity, but do not indicate or imply that an indicated device or element must have a specific orientation or be constructed and operated in a specific orientation. Therefore, it cannot be understood as a limitation on the present application. In addition, the terms such as “first”, “second”, or the like, are only used for distinguishing descriptions and are not intended to indicate or imply relative importance.

It should be further noted that unless specified or limited otherwise, the terms “provided” and “connected” are used broadly, and may be, for example, fixed connections, detachable connections, or integral connections; may be direct connections or indirect connections via intervening structures; may also be communication of two elements. The above terms can be understood by those skilled in the art according to specific situations.

An optical filter with a large-angle low-offset effect is widely applied, may be applied to the fields of 3D imaging, 3D modeling, or the like, and is required to have minimized offset of a center wavelength with an angle even if light is incident at a large angle, so as to guarantee small signal loss and a high signal-to-noise ratio in a wide view field angle. A film of the optical filter is mainly manufactured by mutually superimposing a hydrogenated silicon material with a high refractive index and a material with a low refractive index for coating.

Currently, fabrication of the hydrogenated silicon material is mainly protected by foreign patents, and in order to get rid of stranglehold of a prior art, there exists an urgent need to design a new high refractive index material to replace the hydrogenated silicon material.

On this basis, an embodiment of the present application provides a preparation method of a hydrogenated composite film, which may prepare a high refractive index material with a refractive index greater than 3.5 and an extinction coefficient less than 0.005 under a wavelength of 700 nm to 1800 nm, and base materials, such as glass, or the like, are coated with the high refractive index materials and low refractive index materials alternately to form optical interference film band-pass, long-wave-pass, short-wave-pass and other optical filters. Narrow-band optical filters manufactured with the preparation method according to the present application may be applied as optical filters requiring the large-angle low-offset effect, such as night vision, 3D imaging, 3D modeling, face recognition, iris recognition, gesture recognition and other optical filters, and may also be used in sensor systems of automobile automatic driving, electrochromic window glass, or the like.

Specifically, the embodiment of the present application provides a preparation method of a hydrogenated composite film, including:

S100: introducing inert gas Q and hydrogen H₂ as reaction gas into a reaction chamber, and bombarding at least two materials in the reaction chamber and the introduced hydrogen H₂ using plasma formed by the inert gas Q, such that the at least two materials are sputtered onto a substrate 101 and react with hydrogen ions generated by separation of the hydrogen H₂ to form a hydrogenated composite film layer.

The inert gas Q and the hydrogen H₂ are introduced into the reaction chamber, the inert gas Q forms the plasma and may be argon Ar, the hydrogen H₂ serves as the reaction gas, and the plasma formed by the inert gas Q bombards the at least two materials and the hydrogen H₂ , such that the at least two materials form atom clusters and meanwhile are sputtered onto the substrate 101, and meanwhile, the hydrogen H₂ is bombarded to generate the hydrogen ions to react with the sputtered at least two materials, so as to form the hydrogenated composite film layer on the substrate 101.

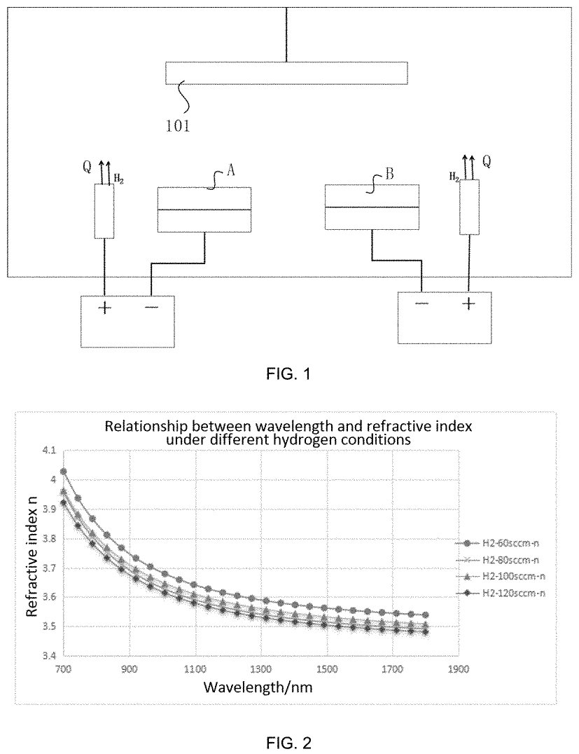

Exemplarily, as shown in FIG. 1, a target material A and a target material B exist in the reaction chamber and may be the above-mentioned two materials or the same target material A or B prepared from the two materials; that is, the two materials may be provided as the target material A and B respectively, or as the target material A or B at the same time.

The required materials are prepared into the target materials, one target material may be prepared from only one material, or one target material may be prepared from two or more materials, which is specifically set according to actual requirements.

The above process is a reactive sputtering process, and reactive sputtering means that a material reacts with reaction gas to form a compound when the material is sputtered in the presence of the reaction gas.

The reaction gas in the present application is the hydrogen H₂ , the hydrogen H₂ is introduced in the sputtering process, the material reacts with the hydrogen H₂ to form the hydrogenated composite film layer on the substrate 101, and the hydrogen H₂ only achieves an activation effect.

During sputtering, a certain vacuum degree is required in the coating chamber, and then, a sputtering source is started, the hydrogen H₂ is introduced, and the material sputtered on the substrate 101 is hydrogenated by the hydrogen H₂ to obtain the hydrogenated composite film layer.

In the preparation method of a hydrogenated composite film according to the embodiment of the present application, the inert gas Q and the hydrogen H₂ are introduced into the reaction chamber, the inert gas Q forms the plasma, the hydrogen H₂ serves as the reaction gas, and the plasma formed by the inert gas Q bombards the at least two materials and the hydrogen H₂ , such that the at least two materials form the atom clusters and meanwhile are sputtered onto the substrate 101, and meanwhile, the hydrogen H₂ is bombarded to generate the hydrogen ions which are also bombarded onto the substrate 101, and the hydrogen ions react with the sputtered at least two materials to form the hydrogenated composite film layer on the substrate 101. The hydrogenated composite film layer obtained with the method includes at least two materials, and the at least two materials are co-sputtered onto the same substrate 101 using a sputtering technology, thereby obtaining a required material performance. The hydrogenated composite film layer with the refractive index greater than 3.5 and the extinction coefficient less than 0.005 under the wavelength of 700 nm to 1800 nm may be obtained by adjusting sputtering parameters and a flow rate of the introduced hydrogen H₂ , and a performance of the hydrogenated composite film layer has advantages compared with an existing hydrogenated silicon material prepared from silicon alone; the hydrogenated composite film fabricated with the preparation method according to the present application has a higher light refractive index and less light absorption, and the offset of the center wavelength with the angle is small in the case where the light is incident at the large angle, such that the optical filter fabricated with the preparation method has a better large-angle low-offset effect. Meanwhile, a limitation that the existing hydrogenated silicon material is subject to the foreign patents is broken through, the high refractive index material may be applied more widely, and a product cost may be reduced.

The at least two materials include a main material and at least one auxiliary material, and the main material includes silicon or germanium; the auxiliary material includes at least one of a semiconductor material, a fourth main group element, and a transition element, the main material and the auxiliary material are different materials, and mass of the auxiliary material accounts for less than 20% of total raw material mass.

The main material and at least one auxiliary material are simultaneously sputtered onto the substrate 101 in the reaction chamber, and the hydrogen H₂ is introduced into the reaction chamber to form the hydrogenated composite film layer on the substrate 101.

The main material includes silicon or germanium; the auxiliary material includes at least one of a semiconductor material, a fourth main group element, and a transition element, and the mass of the auxiliary material accounts for less than 20% of the total raw material mass.

One main material and at least one auxiliary material are required to be sputtered onto the substrate 101, and the mass of the auxiliary material accounts for less than 20% of the total raw material mass; that is, mass of the main material accounts for more than 80% of the total raw material mass.

It should be noted that the mass ratio mentioned herein is a mass ratio of the material before sputtering, instead of a mass ratio after the hydrogenated composite film layer is formed by sputtering onto the substrate 101.

As a main sputtering material, the main material includes silicon or germanium, the silicon has a lower material cost than the germanium, and therefore, the silicon is more widely applied as the main material.

At least one auxiliary material is provided; that is, the main material and the auxiliary material have the following combinations: one main material and one auxiliary material, one main material and two auxiliary materials, one main material and three auxiliary materials, or the like.

The auxiliary material includes at least one of a semiconductor material, a fourth main group element and a transition element; that is, regardless of a number of the auxiliary materials, the auxiliary materials are all from the semiconductor material, the fourth main group element and the transition element. The fourth main group element or transition element refers to the fourth main group element or transition element in the periodic table of chemical elements.

The main material and the auxiliary material are different materials, when the main material is silicon, the auxiliary material cannot be silicon, and when the main material is germanium, the auxiliary material cannot be germanium, so as to ensure that two different materials are sputtered at the same time.

Exemplarily, in a first embodiment of the present application, the main material is silicon, and the auxiliary material is germanium in the fourth main group elements, such that the silicon and germanium are co-sputtered and react with the hydrogen H₂ to form a hydrogenated germanium silicon film layer on the substrate 101.

In a second embodiment of the present application, the main material is silicon, and the auxiliary material is niobium in the transition elements, such that the silicon and niobium are co-sputtered and react with the hydrogen H₂ to form a hydrogenated niobium silicon film layer on the substrate 101.

In a third embodiment of the present application, the main material is silicon, and the auxiliary material is titanium in the transition elements, such that the silicon and titanium are co-sputtered and react with the hydrogen H₂ to form a hydrogenated titanium silicon film layer on the substrate 101.

Certainly, the present application is not limited to the above-mentioned three specific embodiments, and the hydrogenated composite film layer may be formed on the substrate 101 as long as the main material and at least one auxiliary material meeting conditions are co-sputtered and hydrogenated by the hydrogen H₂.

In the fabrication process of the above-mentioned preparation method, the hydrogenated composite film layer with the refractive index greater than 3.5 and the extinction coefficient less than 0.005 under 700 nm to 1800 nm may be obtained by means of sputtering by adjusting a composition proportion of the main material and the auxiliary material, making the main material and the auxiliary material react with the hydrogen H₂ , and meanwhile controlling fabrication parameters. The hydrogenated composite film layer is made of at least two sputtered materials (the main material and at least one auxiliary material) and therefore has better performances than the existing hydrogenated silicon material made of silicon alone; for example, the existing hydrogenated silicon material has a refractive index greater than 3 and an extinction coefficient less than 0.0005 in the wavelength range of 800 nm to 1100 nm; the hydrogenated composite film fabricated in the present application has a higher light refractive index and less light absorption under the same wavelength, and the offset of the center wavelength with the angle is small in the case where the light is incident at the large angle, such that the optical filter formed by the hydrogenated composite film has a better large-angle low-offset effect.

Further, the above-mentioned step S100 specifically includes:

bombarding the at least two materials in the reaction chamber and the introduced hydrogen H₂ using the plasma, such that the at least two materials are sputtered onto the substrate 101 and react with the hydrogen ions generated by the hydrogen H₂ to form the hydrogenated composite film layer.

The plasma is formed by introducing the inert gas Q into the reaction chamber, and the inert gas Q includes argon Ar, or the like.

In order to form a film layer with a preset refractive index and a preset extinction coefficient, the sputtering parameters and the flow rates of the introduced inert gas Q and hydrogen H₂ are required to be controlled to form the hydrogenated composite film layer with a refractive index greater than 3.5 and an extinction coefficient less than 0.005 under the wavelength of 700 nm to 1800 nm; the sputtering parameters include sputtering power, a sputtering time and a sputtering temperature.

Exemplarily, the flow rate of the inert gas Q introduced into the reaction chamber is less than 800 standard milliliters per minute, i.e., 800 sccm, and the flow rate of the introduced inert gas Q is controlled to obtain the hydrogenated composite film layer with the preset refractive index and extinction coefficient.

The flow rate of the hydrogen H₂ introduced into the reaction chamber is less than 400 standard milliliters per minute, and the flow rate of the introduced hydrogen H₂ is controlled to form the hydrogenated composite film layer with the preset refractive index and extinction coefficient.

During specific fabrication, the flow rate of the introduced inert gas Q, the flow rate of the hydrogen H₂ and the sputtering parameters are all required to be controlled, the sputtering parameters include the sputtering power, a sputtering voltage, a sputtering current, the sputtering time, the sputtering temperature, or the like, and the hydrogenated composite film layer with the preset refractive index and extinction coefficient may be obtained by controlling the above-mentioned parameters. In the present application, the hydrogenated composite film layer may have a refractive index greater than 3.5 and an extinction coefficient less than 0.005 under the wavelength of 700 nm to 1800 nm by controlling the above-mentioned parameters.

An embodiment of the present application further discloses an optical filter, including: a substrate 101, a hydrogenated composite film layer fabricated using the preparation method of a hydrogenated composite film according to the above-mentioned embodiment, and a first film layer, the hydrogenated composite film layer and the first film layer being laminated on the substrate 101; the first film layer having a lower refractive index than the hydrogenated composite film layer.

The hydrogenated composite film layer fabricated in the above-mentioned embodiment has a refractive index greater than 3.5 and an extinction coefficient less than 0.005 under a wavelength of 700 nm to 1800 nm, and belongs to a film with a high refractive index and low absorption, the first film layer is laminated on the hydrogenated composite film layer and has a lower refractive index than the hydrogenated composite film layer, and the substrate 101 is alternately coated with the film layers with a high refractive index and a low refractive index, so as to form optical interference film band-pass, long-wave-pass, short-wave-pass and other optical filters.

The first film layer may be a layer of material with a medium-low refractive index, such as silicon oxide, silicon hydroxide, or the like.

Narrow-band optical filters manufactured according to the present application may be applied as optical filters requiring a large-angle low-offset effect, such as night vision, 3D imaging, 3D modeling, face recognition, iris recognition, gesture recognition and other optical filters, and may also be used in sensor systems of automobile automatic driving, electrochromic window glass, or the like.

The hydrogenated composite film layer and the first film layer may be formed on the substrate 101 in a coating mode, and the above-mentioned substrate 101 may be coated with a single hydrogenated composite film layer or the hydrogenated composite film layer and the first film layer in combination; for example, the substrate 101 may be coated with one hydrogenated composite film layer and one first film layer, or plural hydrogenated composite film layers and plural first film layers which are arranged alternately; certainly, during multi-layer coating, the substrate 101 may be coated with one hydrogenated composite film layer firstly, and then with first film layers and hydrogenated composite film layers alternately, or firstly coated with one first film layer and one hydrogenated composite film layer in sequence, and then with first film layers and hydrogenated composite film layers alternately.

Exemplarily, the hydrogenated composite film layer and the first film layer have a total thickness less than 8um which is small, and a small number of layers are laminated on the substrate 101, such that the present application may achieve the same or even better effect as the prior art with a small thickness and fewer layers, and with the present application, the optical filter has a small number of layers, a small total thickness and small angle offset, so as to improve a performance of the optical filter. Certainly, the total thickness of the hydrogenated composite film layer and the first film layer may be set according to specific needs, which is not specifically limited in the embodiment of the present application.

Therefore, in the present application, using the sputtering coating principle, the main material and the auxiliary material are co-sputtered under the action of the inert gas Q according to the composition proportion, and react with the hydrogen H₂ to grow the hydrogenated composite film layer, such that the grown hydrogenated composite film layer has a high refractive index and lower absorption.

The obtained hydrogenated composite film layer has a refractive index greater than 3.5 and an extinction coefficient less than 0.005 under the wavelength of 700 nm to 1800 nm, and base materials, such as glass, or the like, are alternately coated with the designed hydrogenated composite film layers as high-refractive-index materials and low refractive index materials, such as silicon oxide, silicon hydroxide, or the like, so as to form the optical interference film band-pass, long-wave-pass, short-wave-pass and other optical filters which may be applied as optical filters requiring the large-angle low-offset effect.

The above-mentioned preparation method and resulting optical filter are specifically explained below with sputtering of silicon and germanium onto the substrate 101 as an example.

In the present application, using the co-sputtering coating principle, a silicon target and a germanium target are co-sputtered under the action of the inert gas Q (such as argon, or the like) according to a composition proportion, and react with the hydrogen H₂ to grow hydrogenated germanium silicon, and the hydrogenated germanium silicon layer grown with the method has a high refractive index and lower absorption.

Specifically, in a vacuum sputtering coating machine, the plasma generated by the inert gas Q (such as argon) is used to bombard a semiconductor silicon material and a germanium material in a single crystal or polycrystalline form, such that the silicon material and the germanium material are sputtered onto the glass substrate 101 in a nanometer size, and the hydrogen H₂ in a corresponding proportion is introduced to react with the germanium-silicon mixed material for hydrogenation, so as to finally form a hydrogenated germanium silicon film.

During fabrication of a film with a high refractive index, the composition proportion of the silicon material and the germanium material is firstly adjusted usually using related parameters, such as power, a voltage, a current, or the like, and meanwhile, the flow rate of the filled inert gas Q (such as argon, or the like) is controlled, and then, the flow rate of the hydrogen H₂ as reaction gas is controlled, so as to fabricate the film layer with a refractive index greater than 3.5 and an extinction coefficient less than 0.005 under the wavelength of 700 nm to 1800 nm.

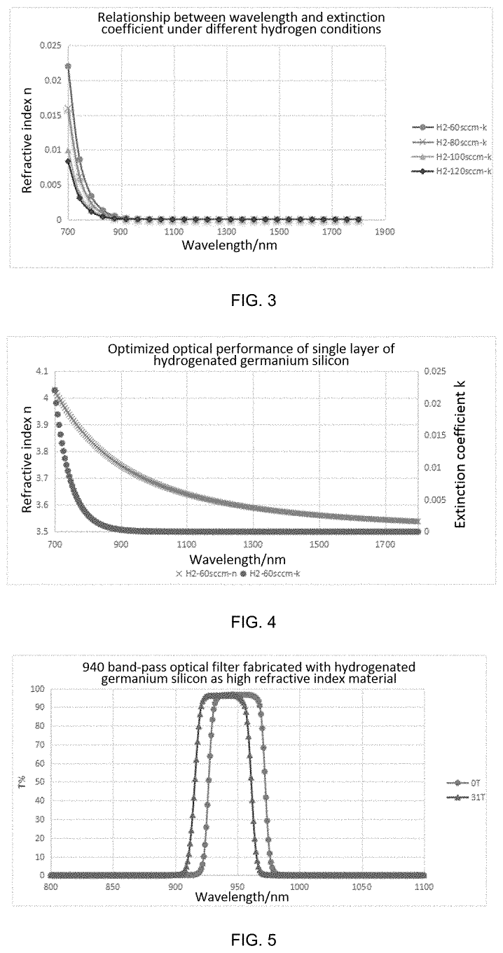

A relationship between the wavelength and the refractive index under different hydrogen H₂ conditions is shown in FIG. 2, and a relationship between the wavelength and the extinction coefficient under different hydrogen H₂ conditions is shown in FIG. 3.

In an optimized case, as shown in FIG. 4, hydrogenated germanium silicon has a refractive index n greater than 3.69 and an extinction coefficient k less than 0.00006 at the wavelength of 940 nm.

It should be particularly noted that the composition proportion of the silicon material and the germanium material as reaction sources (in which a ratio of germanium ingredients is controlled within 20%), the flow rate of the inert gas Q (such as argon, the total flow rate of which is usually controlled within 800 sccm), and the flow rate of the hydrogen H₂ (the total flow rate of the hydrogen H₂ is usually controlled within 400 sccm) are important parameters. If a film with a high refractive index and small absorption is required to be obtained, corresponding parameters, such as a sputtering rate, the sputtering temperature, or the like, are required to be adjusted in cooperation, and specific values of the parameters of different machines have some differences.

Based on corresponding process parameters of hydrogenated germanium silicon under an optimized condition, a multilayer overlapping structure (in which a film layer structure is, for example, hydrogenated germanium silicon+silicon oxide+hydrogenated germanium silicon+silicon oxide+. . . ) is formed in conjunction with silicon oxide films with a low refractive index, and a band-pass optical filter with a center wavelength of 940nm and small offset at a large angle is designed and fabricated. FIG. 5 shows a plot of a measured spectrum of the fabricated 940 nm band-pass optical filter at an incident angle of 0°/31°, center wavelength offset at 0° and 31° is less than 11 nm, and highest transmittance is greater than 97%.

In summary, in the embodiment of the present application, at least two materials (the main material and auxiliary material) are co-sputtered onto the same substrate 101 using the sputtering technology to obtain the required material performance; a series of hydrogenated composite film layers with the refractive index n greater than 3.5 and the extinction coefficient k less than 0.005 under the wavelength of 700 nm to 1800 nm are obtained by adjusting the coating process parameters; for example, hydrogenated silicon germanium film layers may be fabricated from silicon and germanium.

In terms of film system design, the band-pass optical filter with small offset of the center wavelength at large-angle incidence is fabricated by forming a multilayer overlapping structure by high-refractive-index hydrogenated germanium silicon films and materials with a lower refractive index (for example, medium-low refractive index films, such as silicon oxide, silicon hydroxide, or the like). A film layer structure is, for example, an alternating structure of hydrogenated germanium silicon+silicon oxide/silicon hydroxide+hydrogenated germanium silicon+silicon oxide/silicon hydroxide+. . . . The hydrogenated germanium silicon film fabricated in the present application is realized based on the composition proportion, and the proportion of the germanium ingredients as the auxiliary material is controlled within 20%. A germanium-silicon mixed material prepared according to the composition proportion and the hydrogen H₂ may also realize the high-refractive-index hydrogenated germanium silicon film by means of sputtering. In the present application, the hydrogenated germanium silicon film with the high refractive index is fabricated by coating using the co-sputtering coating technology, such that the hydrogenated silicon material may be replaced, the transmittance of plural films may be improved, and meanwhile, the designed optical filter has fewer layers, a small total thickness and lower angle offset.

The above description is only embodiments of the present application and is not intended to limit the protection scope of the present application, and various modifications and changes may be made to the present application by those skilled in the art. Any modification, equivalent replacement, or improvement made within the spirit and principle of the present application shall be included in the protection scope of the present application.

### INDUSTRIAL APPLICABILITY

The performance of the hydrogenated composite film in the embodiment of the present application has advantages compared with the existing hydrogenated silicon material prepared from silicon alone. The hydrogenated composite film fabricated in the present application has a higher light refractive index and less light absorption, and the offset of the center wavelength with the angle is small in the case where the light is incident at the large angle, such that the optical filter formed by the hydrogenated composite film has a better large-angle low-offset effect. Meanwhile, the limitation that the existing hydrogenated silicon material is subject to the foreign patents is broken through, the high refractive index material may be applied more widely, and the product cost may be reduced.

1. A preparation method of a hydrogenated composite film, comprising:
introducing inert gas and hydrogen into a reaction chamber, and bombarding at least two materials in the reaction chamber and introduced hydrogen using plasma formed by the inert gas, such that the at least two materials are sputtered onto a substrate and react with hydrogen ions generated by the hydrogen to form a hydrogenated composite film layer.

2. The method according to claim 1, wherein the at least two materials comprise a main material and at least one auxiliary material, and the main material comprises silicon or germanium; and the auxiliary material comprises at least one of a semiconductor material, a fourth main group element, and a transition element, and the main material and the auxiliary material are different materials.

3. The method according to claim 2, wherein the main material is silicon, and the auxiliary material is germanium; or the main material is silicon, and the auxiliary material is niobium; or the main material is silicon, and the auxiliary material is titanium.

4. The method according to claim 3, wherein a mass of the auxiliary material accounts for less than 20% of total raw material mass.

5. The method according to claim 1, wherein introducing the inert gas and the hydrogen as a reaction gas into the reaction chamber and bombarding at least two materials in the reaction chamber and the introduced hydrogen using the plasma formed by the inert gas such that the at least two materials are sputtered onto the substrate and react with the hydrogen ions generated by the hydrogen to form the hydrogenated composite film layer comprises:
controlling sputtering parameters and flow rates of the introduced inert gas and the hydrogen to form the hydrogenated composite film layer with a refractive index greater than 3.5 and an extinction coefficient less than 0.005 under a wavelength of 700 nm to 1800 nm.

6. The method of according to claim 5, wherein the sputtering parameters comprise sputtering power, a sputtering voltage, a sputtering current, a sputtering time and a sputtering temperature.

7. The method of according to claim 1, wherein one or more target materials exist in the reaction chamber, the target materials are prepared from the materials, one target material may be prepared from only one material, or one target material may be prepared from two or more materials.

8. The method of a hydrogenated composite film according to claim 1, wherein the inert gas introduced into the reaction chamber has a flow rate less than 800 standard milliliters per minute.

9. The method according to claim 1, wherein the hydrogen introduced into the reaction chamber has a flow rate less than 400 standard milliliters per minute.

10. The method of according to claim 1, wherein the inert gas is argon.

11. An optical filter, comprising: a substrate, a hydrogenated composite film layer laminated on the substrate and fabricated using the method of a hydrogenated composite film according to claim 1, and a first film layer; the first film layer having a smaller refractive index than the hydrogenated composite film layer.

12. The optical filter according to claim 11, wherein the substrate is provided with a plurality of hydrogenated composite film layers and a plurality of first film layers, and the plurality of hydrogenated composite film layers and the plurality of first film layers are arranged alternately.

13. The optical filter according to claim 11, wherein the first film layer is a medium-low refractive index material layer.

14. The optical filter according to claim 11, wherein the first film layer is made of silicon oxide, silicon hydroxide.

15. The method according to claim 2, wherein introducing the inert gas and the hydrogen as a reaction gas into the reaction chamber and bombarding at least two materials in the reaction chamber and the introduced hydrogen using the plasma formed by the inert gas such that the at least two materials are sputtered onto the substrate and react with the hydrogen ions generated by the hydrogen to form the hydrogenated composite film layer comprises:
controlling sputtering parameters and flow rates of the introduced inert gas and the hydrogen to form the hydrogenated composite film layer with a refractive index greater than 3.5 and an extinction coefficient less than 0.005 under a wavelength of 700 nm to 1800 nm.

16. The method according to claim 3, wherein introducing the inert gas and the hydrogen as a reaction gas into the reaction chamber and bombarding at least two materials in the reaction chamber and the introduced hydrogen using the plasma formed by the inert gas such that the at least two materials are sputtered onto the substrate and react with the hydrogen ions generated by the hydrogen to form the hydrogenated composite film layer comprises:
controlling sputtering parameters and flow rates of the introduced inert gas and the hydrogen to form the hydrogenated composite film layer with a refractive index greater than 3.5 and an extinction coefficient less than 0.005 under a wavelength of 700 nm to 1800 nm.

17. The method according to claim 2, wherein one or more target materials exist in the reaction chamber, the target materials are prepared from the materials, one target material may be prepared from only one material, or one target material may be prepared from two or more materials.

18. The method according to claim 2, wherein the inert gas introduced into the reaction chamber has a flow rate less than 800 standard milliliters per minute.

19. The method according to claim 2, wherein the hydrogen introduced into the reaction chamber has a flow rate less than 400 standard milliliters per minute.

20. The method according to claim 2, wherein the inert gas is argon.
